(19) United States
(12) Patent Application Publication
(10) Pub. No.: US 2006/0094214 A1
(43) Pub. Date: May 4, 2006

(54) Semiconductor doping process

(75) Inventors: Chi-Ching Huang, Taipei City (TW); Ching-Chu Tseng, Keelung City (TW)

Correspondence Address: BIRCH STEWART KOLASCH & BIRCH, PO BOX 747, FALLS CHURCH, VA, 22040-0747, US

(73) Assignee: LITE-ON SEMICONDUCTOR CORP.

(21) Appl. No.: 11/199,159

(22) Filed: Aug. 9, 2005

(30) Foreign Application Priority Data
Nov. 2, 2004 (TW) 93133396

(51) Int. Cl. H01L 21/22; H01L 21/38

(52) U.S. Cl. 438/542

(57) ABSTRACT

A semiconductor doping process uses hydrogen in a diffusion furnace to prevent platinum/gold atoms from gathering around a defect area of the semiconductor wafer. Platinum/gold atom aggregation caused by a micro defect in the semiconductor wafer is prevented in order to stabilize the semiconductor doping process and to improve reverse recover time (TRR) to further improve yield rate.

### BACKGROUND OF THE INVENTION

1. Field of the Invention

The present invention relates to a semiconductor doping processes, and more particularly to a semiconductor doping process that dopes platinum or gold atoms into semiconductor wafer to achieve a required reverse recover time (TRR).

2. Description of the Related Art

Reverse recover time (TRR) is one of the switching characteristics of PN junction of semiconductor, generally referring to the time needed for electric charges stored in the semiconductor to re-combine when a PN junction switches from the forward-biased, turned-on state to the reversed-biased, blocking state. FIG. 1 is a diagram illustrating the characteristics of PN junction of a conventional semiconductor, in which the latitudinal direction represents time (T) and the longitudinal direction represents the value of current (I) flowing through the semiconductor. As shown in FIG. 1, when the PN junction is forward-biased with a positive current value I, it would take a reverse recover time (TRR) for the PN junction to be reverse-biased and to enter the blocking state. Semiconductor switches must be able to switch quickly between the forward-biased and reverse-biased states. Therefore, a TRR should be as short as possible to enhance switching efficiency and to reduce switching loss.

In current semiconductor processes, the duration of a TRR depends on a variety of dopants and the amount of dopant atoms doped. In a semiconductor doping process, platinum or gold is used as dopant for controlling TRR of the semiconductor, to provide a recombination center to reduce the lifetime of minority carrier of the semiconductor wafer to reduce TRR.

FIG. 2 is a diagram illustrating a conventional semiconductor wafer. During a CZ or FZ process, it is inevitable that impurities such as carbon and oxygen particles and vacancies 104 be incorporated in the semiconductor wafer 10. The impurities then combine with silicon to generate carbide (such as Sic) 100 or oxide (such as Sio/SiOx) 102, thus forming what are conventionally known as micro defects in the semiconductor wafer.

As described above, micro defects and vacancies create a stress zone in the semiconductor lattice, and during a gold or platinum doping process, the stress zone attracts platinum or gold atoms 202 to gather therein. FIG. 4 is a diagram illustrating platinum or gold atoms gathering in the micro defects. When the semiconductor device is in the reversed-biased state, the area where the platinum/gold atoms 202 are gathered tends to be susceptible to a high electric field, accompanied by a higher leakage current and soft breakdown phenomenon. Consequently, the reverse-biased characteristic of the semiconductor device is undermined, leading to a less stable process and a lower yield rate.

### SUMMARY OF THE INVENTION

Due to the diffusion characteristics of hydrogen gas and platinum/gold atoms in the semiconductor wafer, the present invention introduces hydrogen gas in the diffusion furnace during the doping process. The smaller particle size and faster diffusion speed of hydrogen atoms make it easy for hydrogen atoms to gather around vacancies, and stress zones created by micro defects beforehand, to prevent platinum/gold atoms 202 aggregation caused by micro defects to stabilize the process and to improve yield rate.

Reference is made to the detailed description and drawing for better understanding of the characteristics and techniques of the present invention; however, the appended drawings are used for reference only, and do not constitute limitations on the scope of the present invention.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a diagram illustrating the switching characteristics of PN junction of a semiconductor;

FIG. 2 is a diagram illustrating a conventional semiconductor wafer;

FIG. 3 is a diagram illustrating conventional platinum or gold layer forming on the semiconductor wafer;

FIG. 4 is a diagram illustrating platinum or gold atoms gathering in the micro defects;

FIG. 5 is a diagram illustrating present invention using hydrogen gas to prevent gathering of platinum/gold atoms in a defect area of the semiconductor wafer; and

FIG. 6 is a flow chart of the present invention.

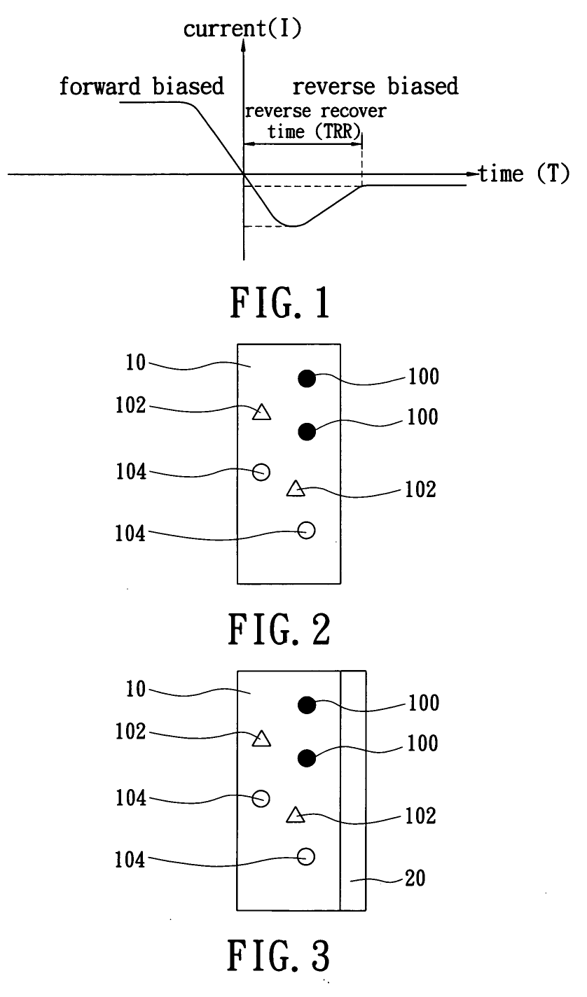

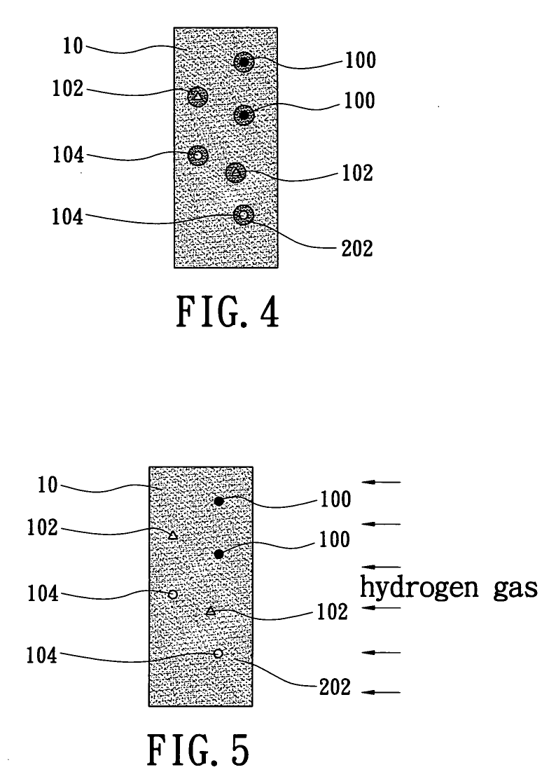

### DETAILED DESCRIPTION OF PREFERRED EMBODIMENTS

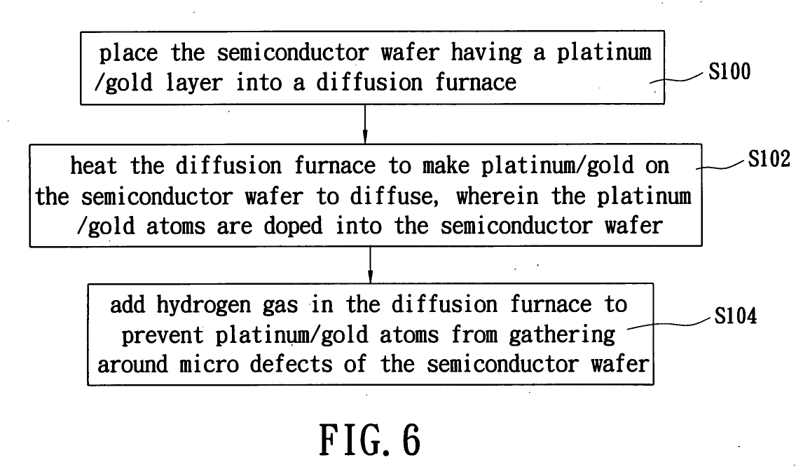

The present invention relates to a doping process for doping platinum or gold atoms into a semiconductor wafer in a diffusion furnace. The present invention is illustrated in FIG. 5 with steps described in FIG. 6. In step S100, a platinum/gold doping layer is formed on the surface of the semiconductor wafer. Reference is also made to FIG. 3, which is a diagram illustrating formation of a conventional platinum or gold layer on the semiconductor wafer. The platinum/gold doping layer 20 is formed on the semiconductor wafer by a coating process with a liquid compound consisting of platinum/gold. Similarly, an evaporation process is also applicable in forming the platinum/gold doping layer on semiconductor wafer.

Second, in step S102, the semiconductor wafer is placed in a diffusion furnace and the diffusion furnace is heated to make the platinum/gold on the semiconductor wafer diffuse. The platinum/gold atoms are thus doped into the semiconductor wafer.

Finally, in step S104, during the diffusion of platinum/gold, hydrogen gas is introduced into the diffusion furnace. The smaller particle size and faster diffusion speed of hydrogen atoms make it easy for hydrogen atoms to gather beforehand around vacancies and stress zones created by micro defects, to prevent platinum/gold atoms 202 aggregation caused by micro defects. The process is thus stabilized, the reversed-biased characteristics of the semiconductor wafer are enhanced and the yield rate is enhanced.

In practice, a combination of nitrogen gas and hydrogen gas can be used, and the concentration of hydrogen gas can be adjusted by changing the flow volume of nitrogen and hydrogen. When the concentration of hydrogen gas is above 5%, platinum/gold atoms are effectively prevented from gathering around defect areas of the semiconductor wafer.

Although the present invention has been described with one of the preferred embodiments shown, one of ordinary skilled in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A semiconductor doping process for doping platinum/gold into a semiconductor wafer in a diffusion furnace, comprising the following steps:
forming platinum/gold on said semiconductor wafer;
heating said diffusion furnace to diffuse platinum/gold on said semiconductor wafer in said diffusion furnace to dope platinum/gold atoms into said semiconductor wafer; and
adding hydrogen into said diffusion furnace to prevent platinum/gold atoms from gathering around a micro defect of said semiconductor wafer.

2. The semiconductor doping process of claim 1, wherein the platinum/gold is formed on said semiconductor wafer in a coating process.

3. The semiconductor doping process of claim 1, wherein the platinum/gold is formed on said semiconductor chip by an evaporation process.

4. The semiconductor doping process of claim 1, wherein said diffusing step is performed at a under a specific temperature for a specific time.

5. The semiconductor doping process of claim 1, wherein a concentration of hydrogen in said diffusion furnace is between about 5% and 100%.
